(19) United States
(12) Patent Application Publication
(10) Pub. No.: US 2025/0105062 A1
(43) Pub. Date: Mar. 27, 2025

(54) SEMICONDUCTOR DEVICE AND MISALIGNMENT MEASUREMENT METHOD FOR SEMICONDUCTOR DEVICE

(71) Applicant: LAPIS Semiconductor Co., Ltd., Yokohama-shi (JP)

(72) Inventor: Takumi TAKAHASHI, Yokohama-shi (JP)

(73) Assignee: LAPIS Semiconductor Co., Ltd., Yokohama-shi (JP)

(21) Appl. No.: 18/897,928

(22) Filed: Sep. 26, 2024

(30) Foreign Application Priority Data
Sep. 27, 2023 (JP) 2023-166481

(51) Int. Cl. H01L 21/66; H01L 23/498; H01L 23/544

(52) U.S. Cl. CPC H01L 22/12; H01L 22/14; H01L 22/32; H01L 23/498; H01L 23/544

(57) ABSTRACT

There is provided a semiconductor device including: a first substrate and a second substrate mounted in an overlapping manner, wherein the first substrate includes: plural conductive first pads that are arranged on a substrate surface of the first substrate at intervals; plural conductive second pads that are arranged on the substrate surface at intervals; and a conductive member, and the second substrate includes: plural conductive third pads; plural conductive fourth pads; a first measurement pad that is measures whether or not the third pad is conductive with the fourth pad; and a second measurement pad that is checks whether or not the third pad is conductive with the fourth pad.

### CROSS-REFERENCE TO RELATED APPLICATION

This application is based on and claims priority under 35 USC 119 from Japanese Patent Application No. 2023-166481 filed on Sep. 27, 2023, the disclosure of which is incorporated by reference herein.

### BACKGROUND

### Technical Field

The present disclosure relates to a semiconductor device and a misalignment measurement method for the semiconductor device.

### Related Art

Hitherto, a process of overlapping two types of chips is known. Japanese Patent Application Laid-Open (JP-A) No. H09-321086 discloses plural substrates to be flip-chip connected. The plurality of substrates include two or more cross-shaped alignment marks in order to improve a yield of flip-chip connection (see FIG. 5 of Japanese Patent Application Laid-Open (JP-A) No. H09-321086).

The alignment mark is formed on each substrate simultaneously with a metal wiring as a test elementary group (TEG) pattern when the metal wiring is formed on each of the plurality of substrates. For this reason, a relative positional relationship between the alignment mark formed on each substrate and the metal wiring is specified. A laser microscope is generally used to measure relative misalignment (hereinafter, also referred to as misalignment) between the alignment mark of one substrate and the alignment mark of the other substrate.

### BRIEF DESCRIPTION OF THE DRAWINGS

Exemplary embodiments of the present invention will be described in detail based on the following figures, wherein:

FIG. 1 is a view illustrating a configuration of a semiconductor device according to an embodiment of the present disclosure;

FIG. 2 is a view illustrating a configuration of the semiconductor device according to an embodiment of the disclosure;

FIG. 3 is an enlarged view of the vicinity of a bump illustrated in FIG. 1;

FIG. 4 is a view illustrating an example of an alignment mark;

FIG. 5 is a view illustrating a configuration example of a measurement structure;

FIG. 6 is a flowchart for describing a misalignment measurement method for the semiconductor device of the disclosure;

FIG. 7 is a view for describing the misalignment measurement method for the semiconductor device of the disclosure;

FIG. 8 is a view for describing the misalignment measurement method for the semiconductor device of the disclosure;

FIG. 9 is a view for describing the misalignment measurement method for the semiconductor device of the disclosure;

FIG. 10 is a block diagram illustrating a hardware configuration of a misalignment measurement device; and

FIG. 11 is a diagram illustrating functional blocks of the misalignment measurement device.

### DETAILED DESCRIPTION

Hereinafter, embodiments will be described with reference to the drawings. The same functions and configurations are denoted by the same or similar reference numerals, and a description thereof will be omitted if appropriate.

### Embodiment

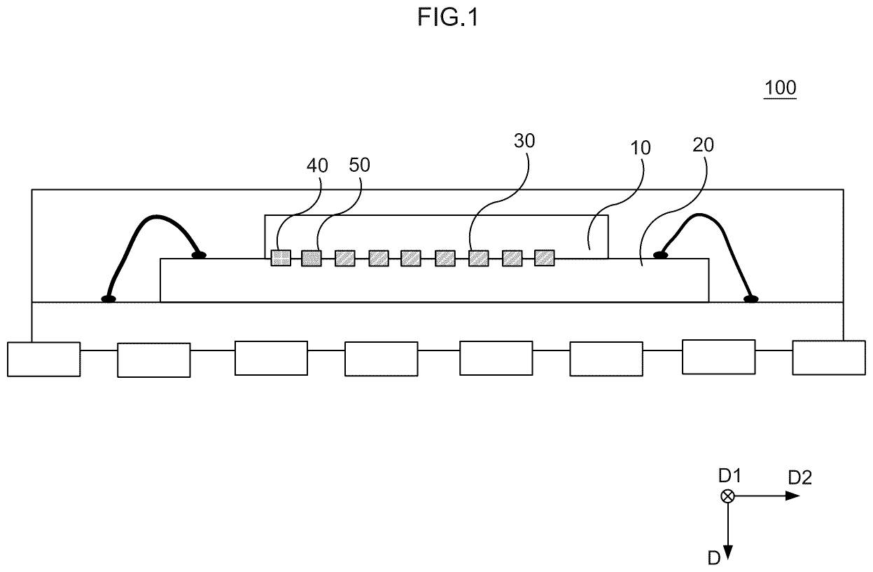

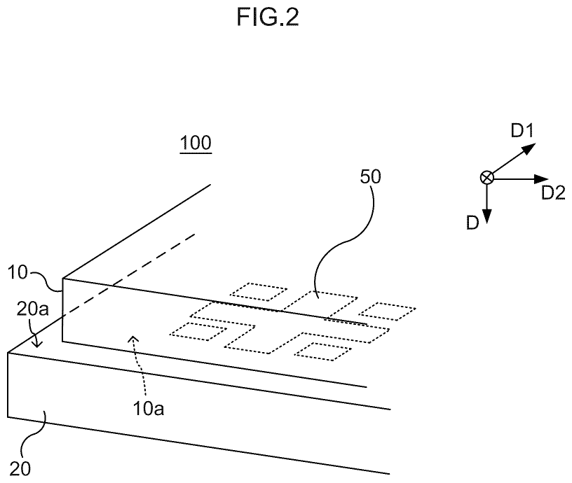

FIGS. 1 and 2 are views illustrating a configuration example of a semiconductor device according to an embodiment of the present disclosure. FIG. 1 illustrates a cross-sectional view of a semiconductor device 100, and FIG. 2 illustrates an external appearance of the semiconductor device 100.

As illustrated in FIG. 1, the semiconductor device 100 may include a first substrate 10 and a second substrate 20 that are mounted in an overlapping manner in a vertical direction in a process. The first substrate 10 may be interpreted as a substrate for a first chip. The second substrate 20 may be interpreted as a substrate for a second chip. The vertical direction may be interpreted as a relative positional relationship in a direction D which is a specific direction.

In the process, the first substrate 10 is brought into close contact with the second substrate 20 by bumps 30 arranged in an array. Specifically, when the first substrate 10 on which a specific integrated circuit (for example, a seed chip) that is the first chip is mounted is flipped by 180 degrees and then placed in an overlapping manner on the second substrate 20 on which another integrated circuit (for example, a pot chip) that is the second chip is mounted, the first substrate 10 is brought into close contact with the second substrate 20 by the bumps 30 arranged in an array. As a result, two types of chips may be electrically connected.

The bump 30 may be interpreted as a protruding electrode. The plural bumps 30 may be arranged in a direction D1. The direction DI may be interpreted as a direction orthogonal to the direction D. Further, the plural bumps 30 may be arranged in a direction D2. The direction D2 may be interpreted as a direction orthogonal to both the direction D and the direction D1.

The semiconductor device 100 may include a measurement structure 40 and an alignment mark 50. The measurement structure 40 and the alignment mark 50 may be provided between the first substrate 10 and the second substrate 20.

The alignment mark 50 may include a first alignment mark and a second alignment mark.

The first alignment mark may be provided on a substrate surface of the first substrate 10. The substrate surface of the first substrate 10 may be interpreted as a facing surface 10a (see FIG. 2) of the first substrate 10 that faces the second substrate 20.

The second alignment mark may be provided on a substrate surface of the second substrate 20. The substrate surface of the second substrate 20 may be interpreted as a facing surface 20a (see FIG. 2) of the second substrate 20 that faces the first substrate 10. Specific examples of the first alignment mark and the second alignment mark are described below.

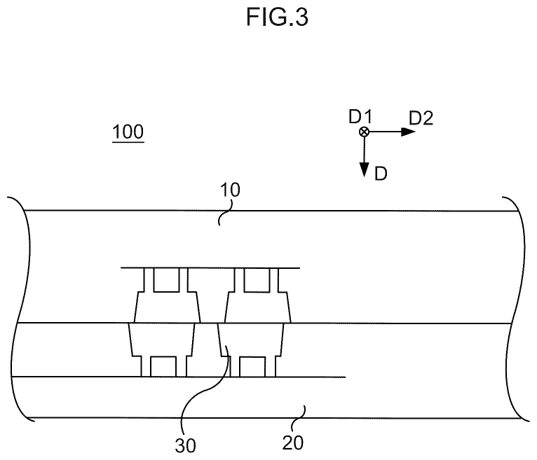

FIG. 3 is an enlarged view of the vicinity of the bump illustrated in FIG. 1. As the first substrate 10 is placed on the second substrate 20 in an overlapping manner, the first substrate 10 may be slightly misaligned with a specific position of the second substrate 20 in one or both of the direction DI and the direction D2. FIG. 3 illustrates a state in which plural electrodes provided on each of the first substrate 10 and the second substrate 20 are slightly misaligned. The electrode can include a conductor mounted on each of the first substrate 10 and the second substrate 20, and the bump 30 described above.

Even in a case where the electrodes are misaligned as described above, conduction between the chip of the first substrate 10 and the chip of the second substrate 20 can be secured as long as the amount of misalignment of the electrodes is within a specific range. On the other hand, when the amount of misalignment of the electrodes is outside the specific range, there is a high possibility that conduction between the chip of the first substrate 10 and the chip of the second substrate 20 is not secured. Therefore, a yield of flip-chip connection can be reduced. In the related art, the amount of misalignment between the first alignment mark and the second alignment mark is measured by a laser microscope in order to suppress deterioration in yield of the flip-chip connection.

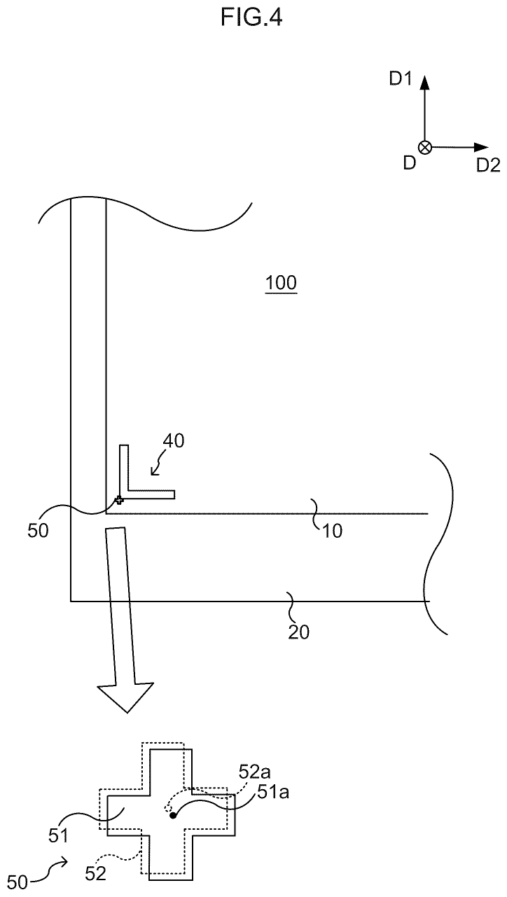

FIG. 4 is a view illustrating an example of the alignment mark. The measurement structure 40 and the alignment mark 50 are illustrated on the upper side of FIG. 4. The measurement structure 40 and the alignment mark 50 are provided between the first substrate 10 and the second substrate 20 in plan view when viewed from the first substrate 10 toward the second substrate 20 in the direction D. The alignment mark 50 may be provided near the measurement structure 40. An enlarged view of the alignment mark 50 illustrated on the upper side of FIG. 4 is illustrated on the lower side of FIG. 4.

The alignment mark 50 may include a cross-shaped first alignment mark 51 and a cross-shaped second alignment mark 52. Since the marks are formed simultaneously with a metal wiring as a test elementary group (TEG) pattern when the metal wiring is formed on the substrate, a relative positional relationship with the metal wiring can be specified. The laser microscope has been generally used to measure the amount of misalignment between the first alignment mark 51 and the second alignment mark 52 in the related art.

The semiconductor device 100 of the disclosure includes the measurement structure 40, and it is possible to measure the presence or absence of misalignment of the electrodes or the two substrates, the amount of misalignment of the electrodes or the two substrates, and the like based on a change in a conductive state of plural conductive members included in the measurement structure 40, that is, a change in electrical connection state of the members. That is, it is possible to measure the presence or absence of misalignment between the electrodes or between the substrates, the amount of misalignment between the electrodes or between the substrates, and the like without using the laser microscope.

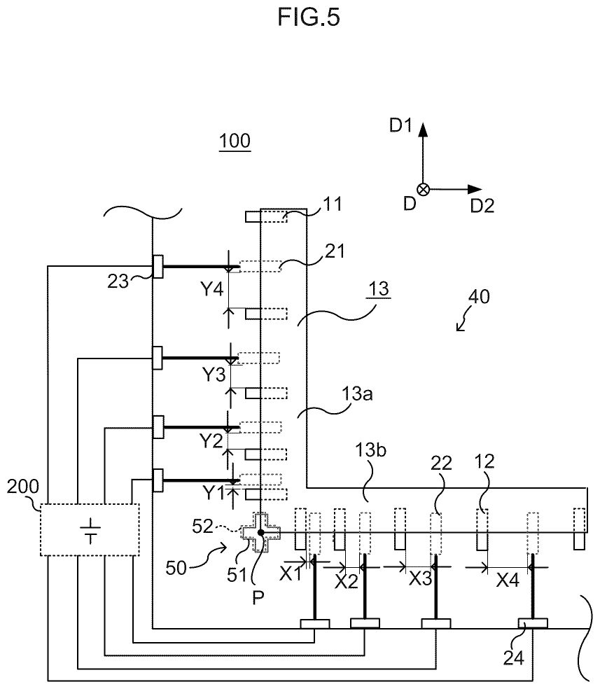

Hereinafter, a configuration of the measurement structure 40 will be specifically described with reference to FIG. 5. FIG. 5 is a view illustrating a configuration example of the measurement structure. FIG. 5 illustrates the measurement structure 40 in plan view of the first substrate 10. Specifically, FIG. 5 illustrates the measurement structure 40 in plan view of the first substrate 10 when viewed from the first substrate 10 toward the second substrate 20 in the direction D. The measurement structure 40 may be provided between the first substrate 10 and the second substrate 20. The measurement structure 40 may include plural conductive members provided on each of the first substrate 10 and the second substrate 20.

### (First Substrate 10)

The first substrate 10 may include plural first pads 11, plural second pads 12, a conductive member 13 having a specific shape, and the first alignment mark 51. The specific shape may be interpreted as an L shape.

### (First Pad 11)

Each of the plural first pads 11 may be interpreted as a conductive terminal, wiring, or electrode. The plural first pads 11 may be provided on a first extending portion 13a of the conductive member 13. Specifically, the plural first pads 11 may be provided on a surface of the first extending portion 13a of the conductive member 13 on a side opposite to the first substrate 10. The surface on the side opposite to the first substrate 10 may be interpreted as a surface of the first extending portion 13a that faces the second substrate 20. The plural first pads 11 may be electrically connected to the first extending portion 13a. Details of a configuration of the conductive member 13 are described below.

The plural first pads 11 may be arranged on the substrate surface of the first substrate 10 (the surface of the first extending portion 13a that faces the second substrate 20) at intervals in the direction D1. The direction DI may be interpreted as a first direction in a virtual plane parallel to the substrate surface of the first substrate 10 in plan view of the first substrate 10. The substrate surface of the first substrate 10 may be interpreted as the facing surface 10a (see FIG. 2) of the first substrate 10 that faces the second substrate 20.

The plural first pads 11 may be arranged on a first virtual line extending in the direction D1. The first virtual line may be interpreted as a virtual line that passes near the center of each of the plural first pads 11 in the direction D2 and is parallel to an arrangement direction of the pads. The first virtual line may be interpreted as a line passing through a central portion 51a (see FIG. 4) or the vicinity of the central portion 51a of the first alignment mark 51.

An interval between two specific adjacent first pads 11 may be set so as to be sequentially increased from the first pad 11 at a position where a distance to a virtual reference point P is the smallest toward the first pad 11 at a position where the distance to the reference point P is the largest.

The reference point P may be interpreted as a portion overlapping the central portion 51a (see FIG. 4) of the first alignment mark 51. The central portion 51a of the first alignment mark 51 may be interpreted as a portion where the center of the first alignment mark 51 in the direction D1 and the center of the first alignment mark 51 in the direction D2 overlap each other.

The central portion 51a of the first alignment mark 51 may be interpreted as a position where the first virtual line described above and a second virtual line described below intersect each other.

In order to make the amount of misalignment between the first chip formed on the first substrate 10 and the second chip formed on the second substrate 20 fall within a specific range, a separation distance between the first pad 11 and the third pad 21 in the direction DI may be set to the following value. That is, arrangement positions of the first pad 11 and the third pad 21 in the direction DI may be set so as to secure the following distances.
Distance Y1=2 μm
Distance Y2=4 μm
Distance Y3=6 μm
Distance Y4=8 μm

### (Second Pad 12)

Each of the plural second pads 12 may be interpreted as a conductive terminal, wiring, or electrode. The plural second pads 12 may be provided on a second extending portion 13b of the conductive member 13. Specifically, the plural second pads 12 may be provided on a surface of the second extending portion 13b of the conductive member 13 on a side opposite to the first substrate 10. The surface on the side opposite to the first substrate 10 may be interpreted as a surface of the second extending portion 13b that faces the second substrate 20. The plural second pads 12 may be electrically connected to the second extending portion 13b of the conductive member 13.

The plural second pads 12 may be arranged on the substrate surface of the first substrate 10 (the surface of the second extending portion 13b that faces the second substrate 20) at intervals in the direction D2. The direction D2 may be interpreted as a second direction different from the first direction in the virtual plane parallel to the substrate surface of the first substrate 10 in plan view of the first substrate 10. Specifically, the second direction may be interpreted as a direction orthogonal to the first direction in the virtual plane, or may be interpreted as a direction other than a direction orthogonal to the first direction.

The plural second pads 12 may be arranged on a second virtual line extending in the direction D2. The second virtual line may be interpreted as a virtual line that passes near the center of each of the plural second pads 12 in the direction DI and is parallel to an arrangement direction of the pads. The second virtual line may be interpreted as a line passing through the central portion 51a (see FIG. 4) or the vicinity of the central portion 51a of the first alignment mark 51.

An interval between two specific adjacent second pads 12 may be set so as to be sequentially increased from the second pad 12 at a position where the distance to the virtual reference point P (or the central portion 51a) is the smallest toward the second pad 12 at a position where the distance to the reference point P (or the central portion 51a) is the largest.

In order to make the amount of misalignment between the first chip and the second chip fall within a specific range, a separation distance between the second pad 12 and a fourth pad 22 in the direction D2 may be set to the following value. That is, arrangement positions of the second pad 12 and the fourth pad 22 in the direction D2 may be set so as to secure the following distances.
Distance X1=2 μm
Distance X2=4 μm
Distance X3=6 μm
Distance X4=8 μm

### (Conductive Member 13)

The conductive member 13 may be interpreted as a conductive terminal, wiring, or electrode that electrically connects the plural first pads 11 and second pads 12. The conductive member 13 may be interpreted as a member for electrically connects a first measurement pad 23 and a second measurement pad 24. The conductive member 13 may be provided on the substrate surface of the first substrate 10. Specifically, the conductive member 13 may be provided on the facing surface 10a (see FIG. 2) of the first substrate 10 that faces the second substrate 20.

The conductive member 13 may include the first extending portion 13a extending in the first direction (direction D1) and the second extending portion 13b extending in the second direction (direction D2) from an end portion of the first extending portion 13a.

### (First Extending Portion 13a)

The first extending portion 13a may have a shape extending to a position away from the reference point P by a certain distance in the first direction. The plural first pads 11 may be provided on the first extending portion 13a.

### (Second Extending Portion 13b)

The second extending portion 13b may have a shape extending to a position away from the reference point P by a certain distance in the second direction. The plural second pads 12 may be provided on the second extending portion 13b.

### (Second Substrate 20)

The second substrate 20 may include plural third pads 21, plural fourth pads 22, the first measurement pad 23, the second measurement pad 24, and the second alignment mark 52.

### (Third Pad 21)

Each of the plural third pads 21 may be interpreted as a conductive terminal, wiring, or electrode. The plural third pads 21 may be provided on the substrate surface of the second substrate 20. The plural third pads 21 may be arranged on the substrate surface of the second substrate 20 at intervals in the direction D1. The plural third pads 21 may be disposed so as to overlap the first extending portion 13a of the conductive member 13 up to a position away from the reference point P by a certain distance in the first direction. The substrate surface of the second substrate 20 may be interpreted as the facing surface 20a (see FIG. 2) of the second substrate 20 that faces the first substrate 10.

Each of the plural third pads 21 may be formed so as to be electrically non-contact with the first extending portion 13a of the conductive member 13. Specifically, a thickness of each of the plural third pads 21 in the direction D may be larger than a thickness of each of the plural first pads 11 in the direction D. An insulating film may be provided in a partial region (for example, a region between adjacent first pads 11) of the surface of the first extending portion 13a of the conductive member 13. Therefore, when the first substrate 10 is placed on the second substrate 20 in an overlapping manner, the third pad 21 can be prevented from electrically contacting the first extending portion 13a of the conductive member 13.

The plural third pads 21 may be arranged on a third virtual line extending in the direction D1. The third virtual line may be interpreted as a virtual line that passes near the center of each of the plural third pads 21 in the direction D2 and is parallel to an arrangement direction of the pads. The third virtual line may be interpreted as a line passing through a central portion 52a (see FIG. 4) or the vicinity of the central portion 52a of the second alignment mark 52.

The central portion 52a of the second alignment mark 52 may be interpreted as a position where the third virtual line described above and a fourth virtual line described below intersect each other.

An interval between two specific adjacent third pads 21 may be set so as to be sequentially increased from the third pad 21 at a position where a distance to the central portion 52a of the second alignment mark 52 is the smallest toward the third pad 21 at a position where the distance to the central portion 52a of the second alignment mark 52 is the largest.

### (Fourth Pad 22)

Each of the plural fourth pads 22 may be interpreted as a conductive terminal, wiring, or electrode. The plural fourth pads 22 may be provided on the substrate surface of the second substrate 20. The plural fourth pads 22 may be arranged on the substrate surface of the second substrate 20 at intervals in the direction D2. The plural fourth pads 22 may be disposed so as to overlap the second extending portion 13b of the conductive member 13 up to a position away from the reference point P by a certain distance in the second direction.

Each of the plural fourth pads 22 may be formed so as to be electrically non-contact with the second extending portion 13b of the conductive member 13. Specifically, a thickness of each of the plural fourth pads 22 in the direction D may be larger than a thickness of each of the plural second pads 12 in the direction D. An insulating film may be provided in a partial region (for example, a region between adjacent second pads 12) of the surface of the second extending portion 13b of the conductive member 13. Therefore, when the first substrate 10 is placed on the second substrate 20 in an overlapping manner, the fourth pad 22 can be prevented from electrically contacting the second extending portion 13b of the conductive member 13.

The plural fourth pads 22 may be arranged on the fourth virtual line extending in the direction D2. The fourth virtual line may be interpreted as a virtual line that passes near the center of each of the plural fourth pads 22 in the direction DI and is parallel to an arrangement direction of the pads. The fourth virtual line may be interpreted as a line passing through the central portion 52a (see FIG. 4) or the vicinity of the central portion 52a of the second alignment mark 52.

An interval between two specific adjacent fourth pads 22 may be set so as to be sequentially increased from the fourth pad 22 at a position where the distance to the central portion 52a of the second alignment mark 52 is the smallest toward the fourth pad 22 at a position where the distance to the central portion 52a of the second alignment mark 52 is the largest.

### (First Measurement Pad 23)

Each of plural first measurement pads 23 may be interpreted as a pad for measuring whether or not the third pad 21 is conductive with the fourth pad 22 via the first pad 11, the conductive member 13, and the second pad 12. Each of the plural first measurement pads 23 may be interpreted as a conductive terminal, wiring, or electrode.

The plural first measurement pads 23 may be provided on the facing surface 20a (see FIG. 2) of the second substrate 20 that faces the first substrate 10. The plural first measurement pads 23 may be arranged on the substrate surface (facing surface 20a) of the second substrate 20 at intervals in the direction D1. Each of the plural first measurement pads 23 may be electrically connected to at least one of the plural third pads 21. Positions of the plural first measurement pads 23 are not particularly limited, and may be any positions as long as wirings, connectors, and the like extending from a measurement device 200 are connected.

### (Second Measurement Pad 24)

Each of plural second measurement pads 24 may be interpreted as a pad for measuring whether or not the third pad 21 is conductive with the fourth pad 22 via the first pad 11, the conductive member 13, and the second pad 12. Each of the plural second measurement pads 24 may be interpreted as a conductive terminal, wiring, or electrode.

The plural second measurement pads 24 may be provided on the facing surface 20a (see FIG. 2) of the second substrate 20 that faces the first substrate 10. The plural second measurement pads 24 may be arranged on the substrate surface (facing surface 20a) of the second substrate 20 at intervals in the direction D2. Each of the plural second measurement pads 24 may be electrically connected to at least one of the plural fourth pads 22. Positions of the plural second measurement pads 24 are not particularly limited, and may be any positions as long as wirings, connectors, and the like extending from the measurement device 200 are connected.

The measurement device 200 may be connected to the first measurement pad 23 and the second measurement pad 24. Details of a configuration of the measurement device 200 are described below.

It is desirable that the first measurement pad 23 is provided on each of the plural third pads 21. In addition, it is desirable that the second measurement pad 24 is provided on each of the plural fourth pads 22. As a result, plural current paths can be provided. That is, it is possible to provide plural paths through which the first measurement pad 23 and the second measurement pad 24 are electrically connected. As the plural current paths, a flow rate of a current changes as compared with a case where there is one current path, and thus, the misalignment measurement device 200 can estimate the amount of misalignment of the electrodes or the like based on the current. Specifically, the misalignment measurement device 200 can calculate the amount of misalignment corresponding to a value of the current flowing from the first measurement pad 23 to the second measurement pad 24 by using table information in which the value of the current is associated with the amount of misalignment of the electrodes or the like.

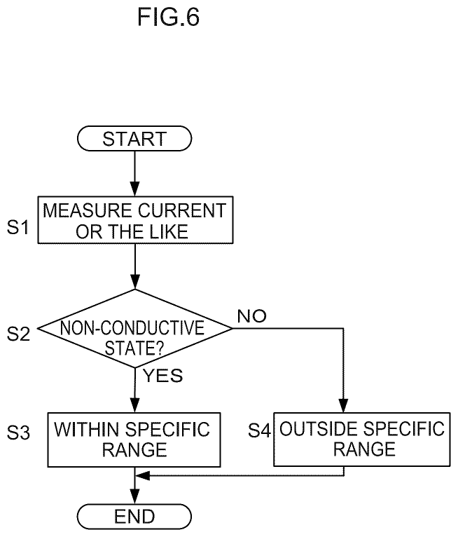

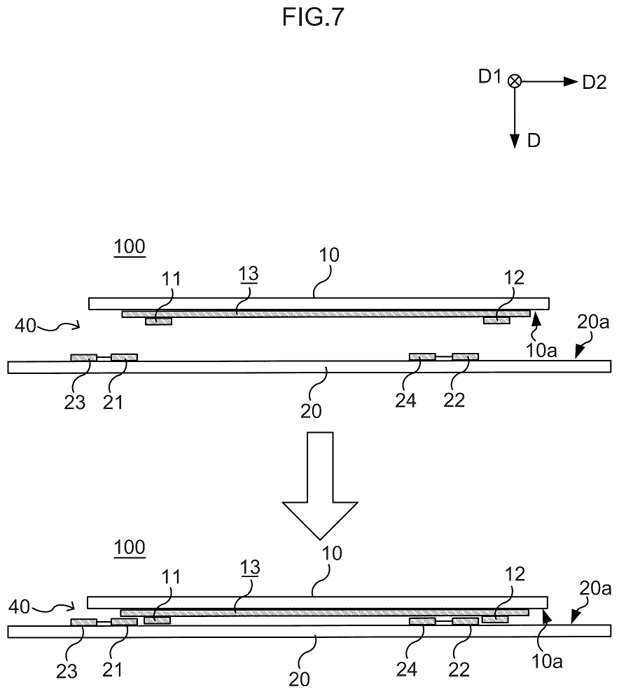

Next, a misalignment measurement method for the semiconductor device 100 will be described with reference to FIGS. 6 to 9. FIG. 6 is a flowchart for describing the misalignment measurement method for the semiconductor device of the disclosure. FIGS. 7, 8, and 9 are views for describing the misalignment measurement method for the semiconductor device of the disclosure.

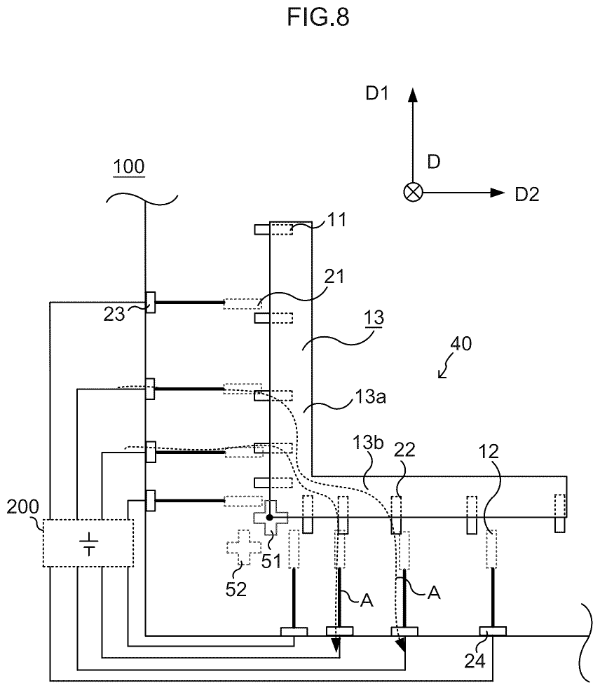

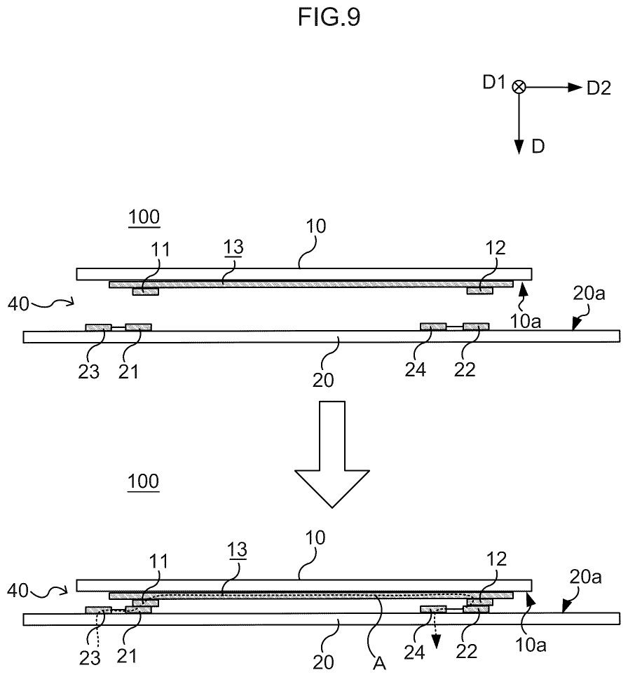

FIG. 7 illustrates the first substrate 10 and the second substrate 20 that are mounted in an overlapping manner such that the amount of misalignment falls within a specific range. The states of the first substrate 10 and the second substrate 20 illustrated in FIG. 7 are the same as the states of the first substrate 10 and the second substrate 20 illustrated in FIG. 5. On the other hand, FIGS. 8 and 9 illustrate the first substrate 10 and the second substrate 20 that are mounted in an overlapping manner such that the amount of misalignment is outside the specific range.

The misalignment measurement method for the semiconductor device 100 may include conduction determination processing of performing conduction determination, and misalignment amount determination processing of determining the presence or absence of misalignment, the amount of misalignment, and the like.

In step S1 illustrated in FIG. 6, in the conduction determination processing, a current flowing through the first measurement pad 23 and the second measurement pad 24, a voltage applied to the first measurement pad 23 and the second measurement pad 24, or the like may be measured (step S1).

Next, in step S2, in the conduction determination processing, it may be determined whether any of the plural third pads 21 is in a non-conductive state or a conductive state with any of the plural fourth pads 22 based on the measured current or the like. That is, it may be determined whether any of the plural first measurement pads 23 is in the non-conductive state or the conductive state with any of the plural second measurement pads 24.

As illustrated in FIG. 7, the non-conductive state may be interpreted as a case where none of the plural third pads 21 is in contact with any of the plural first pads 11, or a case where none of the plural fourth pads 22 is in contact with any of the plural second pads 12.

As illustrated in FIGS. 8 and 9, the conductive state may be interpreted as a case where any of the plural third pads 21 is in contact with any of the plural first pads 11, and any of the plural fourth pads 22 is in contact with any of the plural second pads 12.

For example, in a case where two third pads 21 are in contact with two first pads 11 and two second pads 12 are in contact with two fourth pads 22 as illustrated in FIG. 8, two current paths A are formed.

As illustrated in FIG. 7, in the case of the non-conductive state (YES in Step S2), in step S3, in the misalignment amount determination processing, it may be determined that the amount of misalignment between the first chip formed on the first substrate 10 and the second chip formed on the second substrate 20 is within the specific range.

As illustrated in FIGS. 8 and 9, in the case of the conductive state (Step S2, NO), in step S4, in the misalignment amount determination processing, it may be determined that the amount of misalignment is outside the specific range.

In the misalignment amount determination processing, in a case where one or two current paths A are formed, it may be determined that the amount of misalignment between the first chip formed on the first substrate 10 and the second chip formed on the second substrate 20 is within the specific range. In the misalignment amount determination processing, in a case where three or more current paths A are formed, it may be determined that the amount of misalignment is outside the specific range.

In the misalignment amount determination processing, the amount of misalignment may be determined to be a specific value X (μm) in a case where two current paths A are formed, the amount of misalignment may be determined to be a specific value Y (μm) larger than X in a case where three current paths A are formed, and the amount of misalignment may be determined to be a specific value Z (μm) larger than Y in a case where four current paths A are formed. In the misalignment amount determination processing, in a case where one current path A is formed, it may be determined that the amount of misalignment is a specific value M (μm) smaller than X.

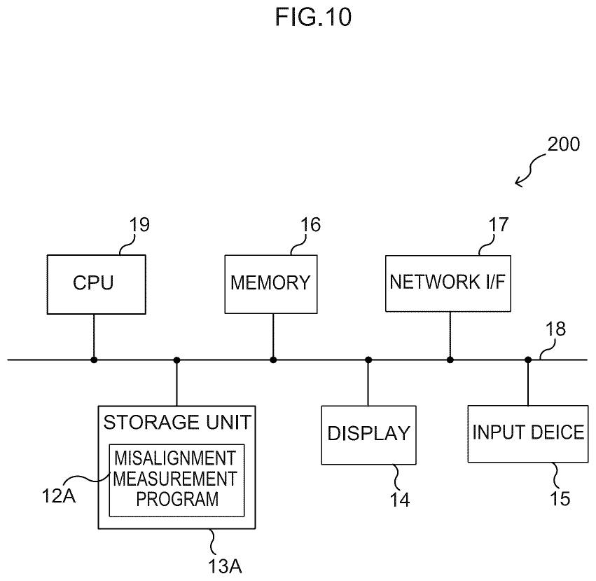

FIG. 10 is a block diagram illustrating a hardware configuration of the misalignment measurement device. The misalignment measurement device 200 includes a central processing unit (CPU) 19, a storage unit 13A that is a nonvolatile memory, a display 14 such as a liquid crystal display, an input device 15, a memory 16 that is a temporary storage area, and a network interface (I/F) 17. The CPU 19, the storage unit 13A, the display 14, the input device 15, the memory 16, and the network I/F 17 are connected to a bus 18.

The CPU 19 may be interpreted as a processor. The input device 15 may include a keyboard or a pointing device such as a mouse. The storage unit 13A can be implemented by a hard disk drive (HDD), a solid state drive (SSD), a flash memory, or the like. The storage unit 13A stores a misalignment measurement program 12A. The CPU 19 may read the misalignment measurement program 12A from the storage unit 13A, load the misalignment measurement program 12A in the memory 16, and execute the loaded misalignment measurement program 12A.

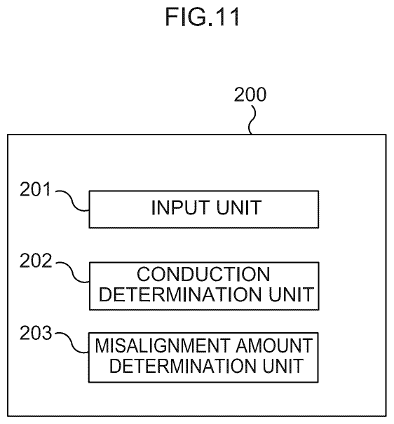

Next, functions of the misalignment measurement device 200 will be described with reference to FIG. 11. FIG. 11 is a diagram illustrating functional blocks of the misalignment measurement device. The misalignment measurement device 200 may include an input unit 201, a conduction determination unit 202, and a misalignment amount determination unit 203. The input unit 201, the conduction determination unit 202, and the misalignment amount determination unit 203 may be implemented by the CPU 19 illustrated in FIG. 10 executing the misalignment measurement program 12A.

### (Input Unit 201)

The input unit 201 may input information indicating the current flowing through the first measurement pad 23 and the second measurement pad 24, the voltage applied to the pads, and the like.

### (Conduction Determination Unit 202)

The conduction determination unit 202 determines whether or not any of the plural third pads 21 is conductive with any of the plural fourth pads 22 based on a value of the current flowing through the first measurement pad 23 and the second measurement pad 24, a value of the voltage, and the like.

### (Misalignment Amount Determination Unit 203)

The misalignment amount determination unit 203 may determine whether the amount of misalignment between the first chip formed on the first substrate 10 and the second chip formed on the second substrate 20 is within a specific range or the amount of misalignment is outside the specific range, and transmit information indicating a determination result to the display 14. The display 14 may include a display control unit, and the display control unit may display the presence or absence of misalignment, the amount of misalignment, and the like based on the information.

### (Actions and Effects)

In the semiconductor device 100 of the disclosure, the first substrate 10 includes the plural first pads 11, the plural second pads 12, and the conductive member 13, and the second substrate 20 includes the plural third pads 21, the plural fourth pads 22, the first measurement pad 23, and the second measurement pad 24. As a result, it is possible to measure the presence or absence of misalignment, the amount of misalignment, and the like between the respective chips of the first substrate 10 and the second substrate 20 mounted in an overlapping manner by changing an electrical connection state of the plural conductive members. Therefore, the amount of misalignment and the like can be easily measured without using a laser microscope.

In addition, since the laser microscope is unnecessary, a time required for setting the laser microscope, maintenance of the laser microscope, and the like can be reduced, and a manufacturing time of the semiconductor device 100 can be further shortened. A manufacturing cost of the semiconductor device 100 can also be reduced.

The following supplementary notes are further disclosed for the above description.

### Supplementary Note 1

A semiconductor device, comprising:
a first substrate and a second substrate mounted in an overlapping manner, wherein:
the first substrate includes:
   a plurality of conductive first pads that are arranged on a substrate surface of the first substrate at intervals in a first direction parallel to the substrate surface in plan view of the first substrate in a specific direction;
   a plurality of conductive second pads that are arranged on the substrate surface at intervals in a second direction that is different from the first direction and is parallel to the substrate surface in plan view of the first substrate in the specific direction; and
   a conductive member that is provided on the substrate surface and electrically connects the plurality of first pads and the plurality of second pads, and the second substrate includes:
   a plurality of conductive third pads that are arranged on a facing surface of the second substrate that faces the first substrate at intervals in the first direction in plan view of the second substrate in the specific direction;
   a plurality of conductive fourth pads that are arranged on the facing surface at intervals in the second direction in plan view of the second substrate in the specific direction;
   a first measurement pad that is connected to at least one of the plurality of third pads and measures whether or not the third pad is conductive with the fourth pad via the first pad, the conductive member, and the second pad; and
   a second measurement pad that checks whether or not the third pad is conductive with the fourth pad via the first pad, the conductive member, and the second pad.

### Supplementary Note 2

The semiconductor device according to Supplementary Note 1, further comprising a second measurement pad that is connected to at least one of the plurality of fourth pads and checks whether or not the third pad is conductive with the fourth pad via the first pad, the conductive member, and the second pad.

### Supplementary Note 3

The semiconductor device according to Supplementary Note 1, wherein:
the conductive member includes a first extending portion extending in the first direction and a second extending portion extending in the second direction from an end portion of the first extending portion,

### Supplementary Note 4

The semiconductor device according to Supplementary Note 3, wherein:
the plurality of first pads are provided on the first extending portion, and
the plurality of second pads are provided on the second extending portion.

### Supplementary Note 5

The semiconductor device according to Supplementary Note 4, wherein:
the first measurement pad is provided on each of the plurality of third pads.

### Supplementary Note 6

The semiconductor device according to Supplementary Note 5, wherein:
the second measurement pad is provided on each of the plurality of fourth pads.

### Supplementary Note 7

A misalignment measurement method for a semiconductor device including a first substrate and a second substrate mounted in an overlapping manner,
the first substrate including:
   a plurality of conductive first pads that are arranged on a substrate surface of the first substrate at intervals in a first direction parallel to the substrate surface in plan view of the first substrate in a specific direction;
   a plurality of conductive second pads that are arranged on the substrate surface at intervals in a second direction that is different from the first direction and is parallel to the substrate surface in plan view of the first substrate in the specific direction; and
   a conductive member that is provided on the substrate surface and electrically connects the plurality of first pads and the plurality of second pads, and the second substrate including:
   a plurality of conductive third pads that are arranged on a facing surface of the second substrate that faces the first substrate at intervals in the first direction in plan view of the second substrate in the specific direction;
   a plurality of conductive fourth pads that are arranged on the facing surface at intervals in the second direction in plan view of the second substrate in the specific direction;
   a first measurement pad that is connected to at least one of the plurality of third pads and measures whether or not the third pad is conductive with the fourth pad via the first pad, the conductive member, and the second pad; and
   a second measurement pad that is connected to at least one of the plurality of fourth pads and checks whether or not the third pad is conductive with the fourth pad via the first pad, the conductive member, and the second pad,
the misalignment measurement method comprising:
determining whether or not any of the plurality of third pads is conductive with any of the plurality of fourth pads by using a measuring instrument connected to the first measurement pad and the second measurement pad; and

### Supplementary Note 8

The misalignment measurement method according to Supplementary Note 7, further comprising determining that an amount of misalignment between a first chip formed on the first substrate and a second chip formed on the second substrate is within a specific range in a case in which none of the plurality of third pads is conductive with any of the plurality of fourth pads.

### Supplementary Note 9

The misalignment measurement method according to Supplementary Note 8, further comprising determining that the amount of misalignment between the first chip and the second chip is outside the specific range in a case in which any of the plurality of third pads is conductive with any of the plurality of fourth pads.

What is claimed is:

1. A semiconductor device, comprising:
a first substrate and a second substrate mounted in an overlapping manner, wherein:
the first substrate includes:
a plurality of conductive first pads that are arranged on a substrate surface of the first substrate at intervals in a first direction parallel to the substrate surface in plan view of the first substrate in a specific direction;
a plurality of conductive second pads that are arranged on the substrate surface at intervals in a second direction that is different from the first direction and is parallel to the substrate surface in plan view of the first substrate in the specific direction; and
a conductive member that is provided on the substrate surface and electrically connects the plurality of first pads and the plurality of second pads, and
the second substrate includes:
a plurality of conductive third pads that are arranged on a facing surface of the second substrate that faces the first substrate at intervals in the first direction in plan view of the second substrate in the specific direction;
a plurality of conductive fourth pads that are arranged on the facing surface at intervals in the second direction in plan view of the second substrate in the specific direction;
a first measurement pad that is connected to at least one of the plurality of third pads and measures whether or not the third pad is conductive with the fourth pad via the first pad, the conductive member, and the second pad.

2. The semiconductor device according to claim 1, further comprising a second measurement pad that is connected to at least one of the plurality of fourth pads and checks whether or not the third pad is conductive with the fourth pad via the first pad, the conductive member, and the second pad.

3. The semiconductor device according to claim 2, wherein:
the conductive member includes a first extending portion extending in the first direction and a second extending portion extending in the second direction from an end portion of the first extending portion.

4. The semiconductor device according to claim 3, wherein:
the plurality of first pads are provided on the first extending portion, and
the plurality of second pads are provided on the second extending portion.

5. The semiconductor device according to claim 4, wherein:
the first measurement pad is provided on each of the plurality of third pads.

6. The semiconductor device according to claim 5, wherein:
the second measurement pad is provided on each of the plurality of fourth pads.

7. A misalignment measurement method for a semiconductor device including a first substrate and a second substrate mounted in an overlapping manner,
the first substrate including:
a plurality of conductive first pads that are arranged on a substrate surface of the first substrate at intervals in a first direction parallel to the substrate surface in plan view of the first substrate in a specific direction;
a plurality of conductive second pads that are arranged on the substrate surface at intervals in a second direction that is different from the first direction and is parallel to the substrate surface in plan view of the first substrate in the specific direction; and
a conductive member that is provided on the substrate surface and electrically connects the plurality of first pads and the plurality of second pads, and
the second substrate including:
a plurality of conductive third pads that are arranged on a facing surface of the second substrate that faces the first substrate at intervals in the first direction in plan view of the second substrate in the specific direction;
a plurality of conductive fourth pads that are arranged on the facing surface at intervals in the second direction in plan view of the second substrate in the specific direction;
a first measurement pad that is connected to at least one of the plurality of third pads and measures whether or not the third pad is conductive with the fourth pad via the first pad, the conductive member, and the second pad; and
a second measurement pad that is connected to at least one of the plurality of fourth pads and checks whether or not the third pad is conductive with the fourth pad via the first pad, the conductive member, and the second pad,
the misalignment measurement method comprising:
determining whether or not any of the plurality of third pads is conductive with any of the plurality of fourth pads by using a measuring instrument connected to the first measurement pad and the second measurement pad.

8. The misalignment measurement method according to claim 7, further comprising determining that an amount of misalignment between a first chip formed on the first substrate and a second chip formed on the second substrate is within a specific range in a case in which none of the plurality of third pads is conductive with any of the plurality of fourth pads.

9. The misalignment measurement method according to claim 8, further comprising determining that the amount of misalignment between the first chip and the second chip is outside the specific range in a case in which any of the plurality of third pads is conductive with any of the plurality of fourth pads.
